(19) United States
(12) Patent Application Publication
(10) Pub. No.: US 2004/0097207 A1
(43) Pub. Date: May 20, 2004

(54) Receiver to determine modulation type

(76) Inventor: Sathiaseelan Sandaralingam, Camberley (GB)

Correspondence Address: SQUIRE, SANDERS & DEMPSEY L.L.P., 14TH FLOOR, 8000 TOWERS CRESCENT, TYSONS CORNER, VA, 22182, US

(21) Appl. No.: 10/433,992

(22) PCT Filed: Sep. 30, 2002
(86) PCT No.: PCT/IB02/04030

(30) Foreign Application Priority Data
Oct. 10, 2001 (GB) 0124321.1

(51) Int. Cl. H04B 1/16; H03D 1/00; H04L 27/06

(52) U.S. Cl. 455/205; 375/340; 455/210

(57) ABSTRACT

This invention relates to a method for determining a modulation method comprising demodulating said method comprising demodulating said received signal using at least two different modulation methods, determining for each demodulated signal an estimate of said channel, said estimate of said channel comprising m taps, selecting n of said taps for each channel estimate, a being less than m, estimating a variance for each demodulated signal based on said n taps, and comparing the estimated variances and based on said comparison making a determination as to the modulation method applied to the received signal.

### FIELD OF THE PRESENT INVENTION

The present invention relates to a method for determining the modulation used. The present invention also relates to a receiver which is able to determine the modulation which has been applied to received data. In particular, but not exclusively, embodiments of the present invention may be used in conjunction with the GSM standard.

### BACKGROUND TO THE INVENTION

Reference is made to FIG. 1, which shows a schematic representation of a known wireless communication network 2. The area covered by the network 2 is divided into a number of cells 4. Each cell 4 has a base station 6. The base stations 6 are arranged to communicate with mobile stations 8, located in the cells. Various standards have been proposed for the communication between the base stations and the mobile stations. One commonly used standard is the GSM (Global System for Mobile Communications) standard. In this standard, the available frequency band is divided up into a number of frequency channels. Those frequency channels are further divided into frames, which are made up of time slots. In a given cell, one mobile station is able to use a given time slot on a given frequency to communicate with the base station. When the base station communicates with the mobile station, it typically uses a different frequency and time slot to communicate with the mobile station. The GSM standard uses a frequency/time division multiple access technique.

As an enhancement to the GSM standard, GPRS (General Packet Radio Service) has been proposed. GPRS is designed to allow data to be transmitted to and by the mobile station.

GPRS can use one of two different modulation schemes. The first modulation scheme is GMSK (Gaussian Minimum Shift Keying) whilst the second method is 8 psk (8-phase shift keying).

The GMSK scheme is used for the coding signals from MCS (modulation & coding scheme) 1-4, whereas MCS5-9 uses 8 psk The receiver receives a signal which has been modulated. However, the modulation which has been applied to the received signal is unknown to the receiver. Accordingly, the receiver needs to make some determination of that modulation. The receiver needs to identify the modulation method used prior to the receiver processing the received signal and carrying out bit detection of the received symbols. Clearly, if the modulation scheme used is not identified, then the information provided by the received signal cannot be identified.

Reference is made to FIG. 2, which shows one previously proposed scheme. In general, this scheme comprises passing the received signal through a GMSK demodulation path 10 and through a 8 psk demodulation path 12. In other words, the received data is demodulated twice, once as if it has the GMSK modulation method applied thereto and once as if the 8psk modulation method has been applied thereto. The results from the two demodulation paths 10 and 12 are compared and an assessment is made as to whether or not the data is likely to have been modulated by the GMSK or by the 8 psk method. The output of one of the two demodulators is then selected for further processing.

In more detail, the GMSK demodulation path 10 comprises a GMSK demodulator 14, which demodulates the received data. The output of the GMSK demodulator is input to a channel estimator 16, which estimates the channel impulse response. The output of the channel estimator 16 is input to a maximum energy and time of arrival correction block 18. This makes a correction for different propagation paths being used and selects the taps having the highest energy. The output of the maximum energy and time of arrival correction block 18 is input to an energy calculator unit 20, which calculates the energy of the received signal. The output of the energy calculator unit 20 is input to a comparator 22.

The 8 psk demodulation path is similar to that of the GMSK demodulation path. However, instead of a GMSK demodulator, an 8 psk demodulator 24 is provided. A channel estimator 16, a maximum energy and time of arrival correction block 18 and an energy calculator 20 are all provided. The comparator 22 compares the energy calculated by the calculator 20 of the GMSK demodulation path with that calculated by the energy calculator 20 of the 8 psk path. The signal which provides the highest impulse response energy is selected. Accordingly, if the signal from the GMSK demodulation path provides the higher impulse response energy, then the signal is considered to have been modulated by GMSK and the GMSK demodulator is used. The output of the 8 psk demodulator is used if the 8 psk demodulation path provides the higher impulse response energy.

However, this method has the disadvantage in that it is not able to deal particularly well where there is adjacent and/or co-channel interference. It has been found that the performance is relatively significantly impaired compared to the case where the receiver is explicitly advised as to the actual modulation method used. Simulations have shown that the losses may be of the order of 1.5 dB in the case of co-channel interference, and of the order of 3 dB in the case of adjacent channel interference.

A second proposed mechanism is shown in FIG. 3. The method shown in FIG. 3 is similar to that shown in FIG. 2 in that a first demodulation path 26 for GMSK demodulation is provided and a second demodulation path 28 is provided for 8 psk demodulation. The GMSK demodulation path 26 comprises a GMSK demodulator 30. The output of the GMSK demodulator is input to a channel estimator 32, which estimates the channel impulse response and provides an 8 tap output. The output of the channel estimator 32 is input to an estimator 34 for estimating the noise variance. This is done using the output of the channel estimator 32 and an output from a memory 36, which stores a known training sequence. The data which is received has a training sequence which is known to the receiver in advance.

The output of the noise variance estimator 34 is input to a comparator 38.

The 8 psk demodulation path 28 comprises a 8 psk demodulator 40, a channel estimator 32, an estimator for estimating the noise variance 34 and a memory 36 for storing the known training sequence. The 8 psk demodulation path 28 operates in a similar manner to that outlined in respect of the GMSK demodulation path 26. The output of the estimator for the noise variance in the 8 psk path 28 is also input to the comparator 38. The variances are compared and based on the results of the comparison, the used modulation method is identified.

However, this method again is not particularly good for dealing with adjacent channel interference and co-channel interference where both signal paths provide very small and equal variances. For example, losses of about 3.5-dB can occur in the case of adjacent channel interference, as compared to the situation where the receiver is advised as to which modulation method is used.

WO 99/39484 discloses a receiver which can receive a transmitted signal. The transmitted signal can have one of a plurality of different modulation methods applied thereto. A number of demodulators are provided, each demodulator using a different demodulation method. The output of the respective demodulators are input to impulse response blocks, which form for the received signal an impulse response which corresponds to each modulation method. The modulation method used for the signal is inferred in a reference block from the impulse response estimate. The signal according to the inferred modulation method is detected in a detector.

The article “Least Sum of Squared Errors (LSSE) channel estimation”, published in IEEE proceedings-F, Vol. 138, No. 4 August 1991, Crozier et al, discloses a Least Sum of Squared Errors channel estimation algorithm. Optimum training sequences are found and tabulated for different channel responses and training sequence lengths. The effect of channel estimation errors on the performance of some data detectors is investigated in this document.

### SUMMARY OF THE INVENTION

It is an aim of embodiments of the present invention to address at least one of the problems described hereinbefore.

According to a first aspect of the present invention there is provided a method for determining a modulation method applied to a received signal, said method comprising demodulating said received signal using at least two different modulation methods, determining for each demodulated signal an estimate of said channel, said estimate of said channel comprising m taps, selecting n of said taps for each channel estimate, n being less than m, estimating a variance for each demodulated signal based on said n taps, and comparing the estimated variances and based on said comparison making a determination as to the modulation method applied to the received signal.

According to a second aspect of the present invention there is provided a method for determining a modulation method applied to a received signal, said method comprising demodulating said received signal using at least two different modulation methods, determining for each demodulated signal an estimate of said channel, estimating a variance for each demodulated signal based on said channel estimates, said variance taking into account a mean error for at least a portion of said received signal, and comparing the estimated variances and based on said comparison making a determination as to the modulation method applied to the received signal..

According to a third aspect of the present invention there is provided a receiver for determining a modulation method applied to a received signal, said receiver comprising means for demodulating said received signal using at least two different modulation methods, means for determining for each demodulated signal an estimate of said channel, said estimate of said channel comprising m taps, means for selecting n of said taps for each channel estimate, n being less than m, means for estimating a variance for each demodulated signal based on said n taps, and means for comparing the estimated variances and based on said comparison making a determination as to the modulation method applied to the received signal.

According to a fourth aspect of the present invention there is provided a receiver for determining a modulation method applied to a received signal, said receiver comprising means for demodulating said received signal using at least two different modulation methods, means for determining for each demodulated signal an estimate of said channel, means for estimating a variance for each demodulated signal based on said channel estimates, said variance taking into account a mean error for at least a portion of said received signal, and means for comparing the estimated variances and based on said comparison making a determination as to the modulation method applied to the received signal.

### BRIEF DESCRIPTION OF THE DRAWINGS

For a better understanding of the present invention and as to how the same may be carried into effect, reference is made by way of example only to the accompanying drawings in which:

FIG. 1 shows a schematic representation of a wireless cellular communications network;

FIG. 2 shows a first previously proposed modulation method;

FIG. 3 shows a second previously proposed modulation method;

FIG. 4 shows the elements of a GSM time slot;

FIG. 5 shows a block diagram of an embodiment of the present invention;

FIG. 6 illustrates schematically the calculation of the variance;

FIG. 7 shows a schematic representation of the output of the channel estimator; and

FIG. 8 shows a receiver in which embodiments of the present invention can be incorporated

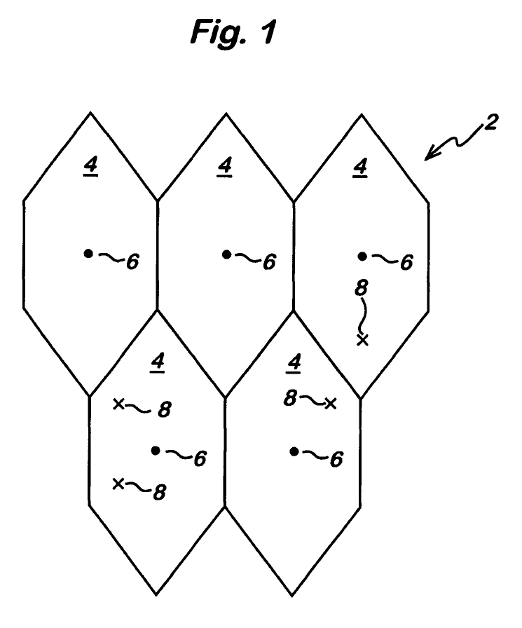

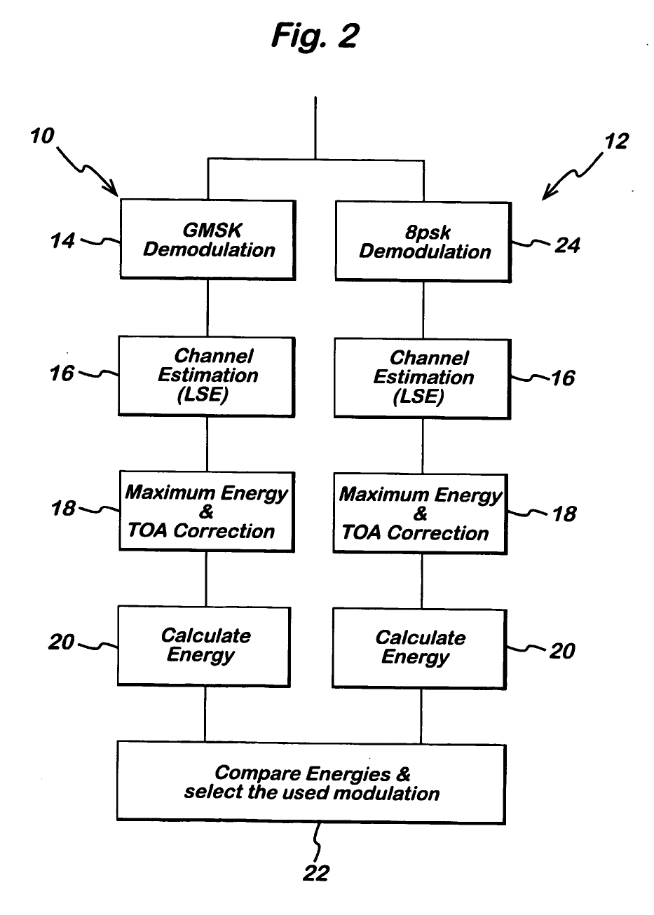

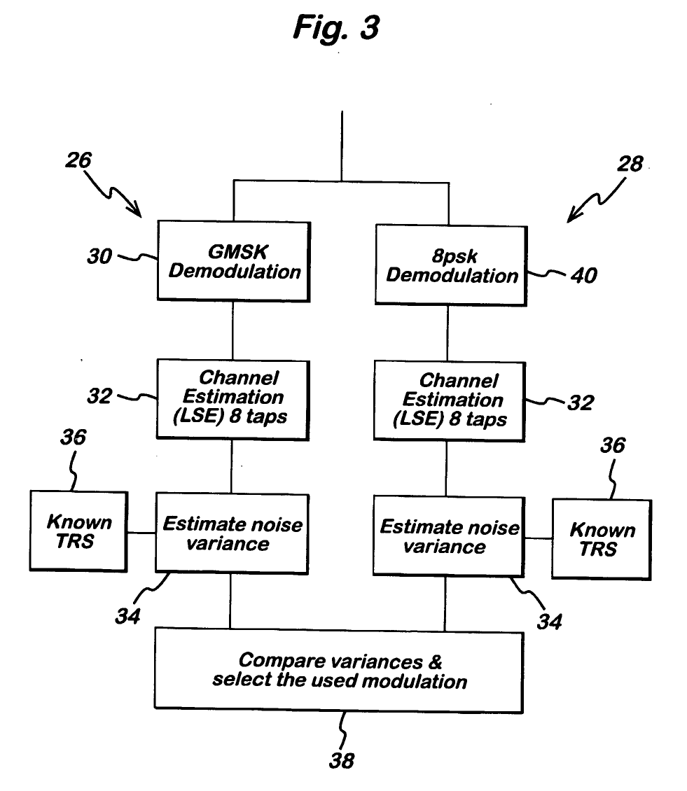

### DETAILED DESCRIPTION OF PREFERRED EMBODIMENTS OF THE PRESENT INVENTION

Embodiments of the present invention will be described in the context of a system which is in accordance with the GSM standard and which is particularly designed to deal with GPRS signals, which are either modulated by the 8psk modulation method or by the GMSK modulation method. However, it should be appreciated that embodiments of the present invention can be used in any communication systems and with any modulation methods. Embodiments of the present invention can be used in any receiver which receives signals of an unknown modulation method.

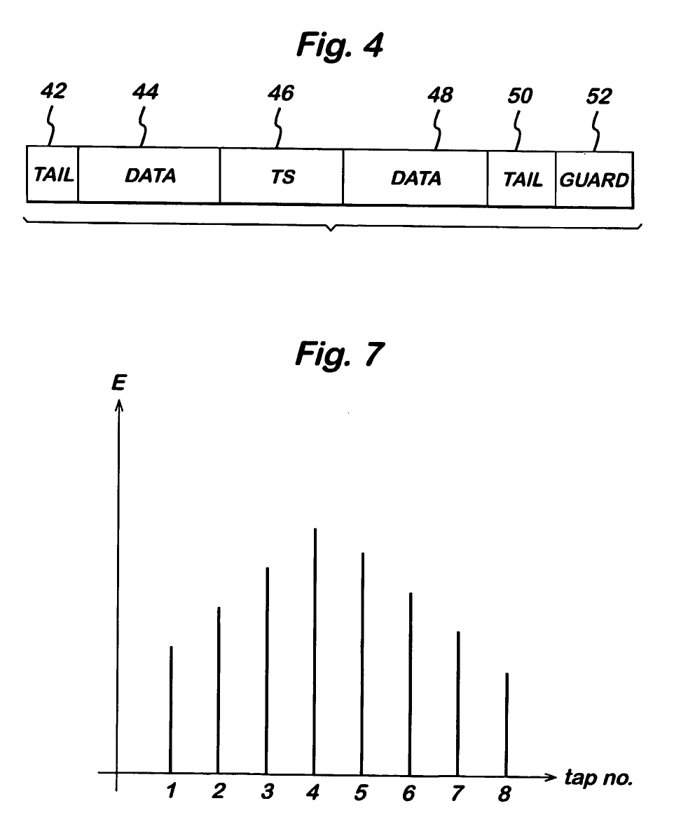

Reference is made to FIG. 4, which shows a basic structure of a time slot in the GSM standard. The first three symbols are a first tail field 42. This is followed by a data field 44 comprising 58 symbols of encrypted data. This is followed by a training sequence field 46 of 26 symbols in length. This is known as a “mid amble” because it comes between two data fields. The training sequence is a sequence of symbols which are known to the receiver. In general terms, the receiver compares the received version of the training sequence with the known version of the training sequence in order to make an estimate of the channel. The training sequence field 46 is followed by a second data field 48, which contains a second set of 58 symbols of encrypted data. This is followed by a second tail field 50 containing 3 symbols. Finally, there is a guard period 52, which is empty.

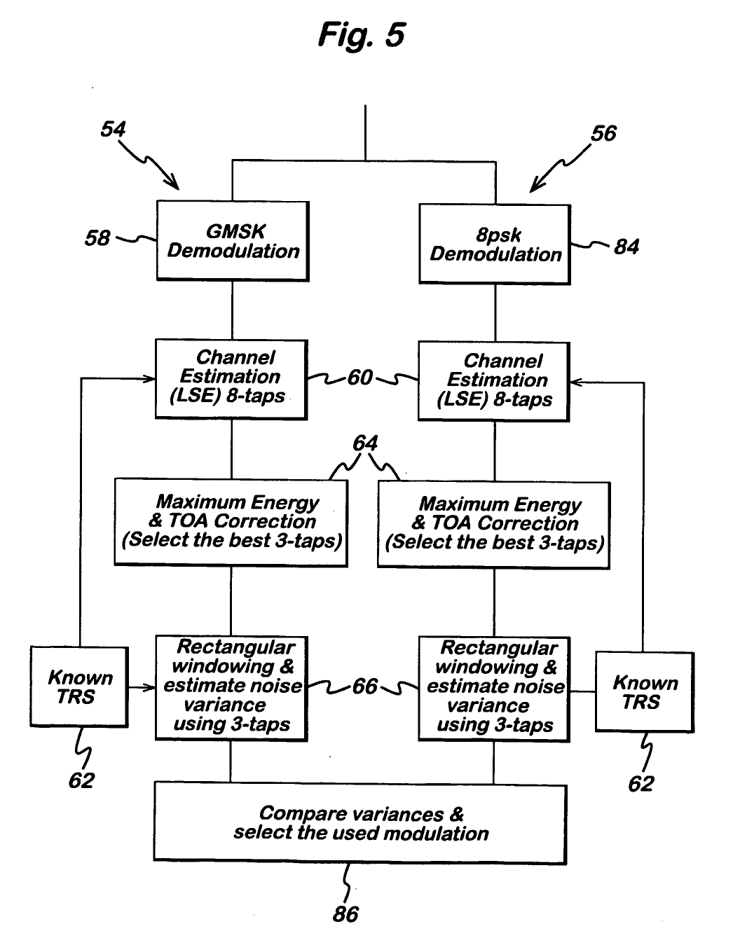

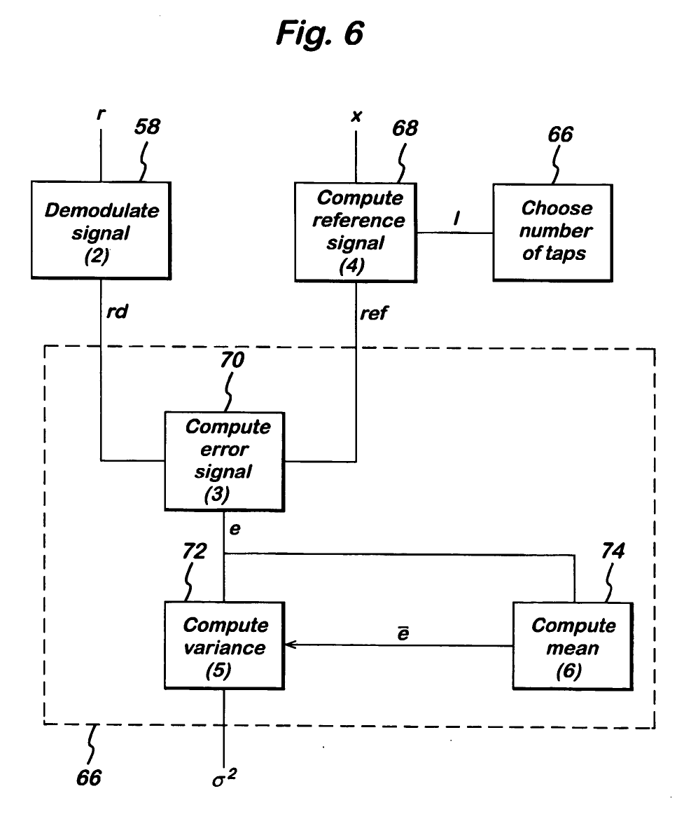

Reference is now made to FIGS. 5 and 6, which illustrate an embodiment of the present invention. FIG. 5 illustrates a first demodulation path 54, which is arranged to perform GMSK demodulation and a second demodulation path 56, which is arranged to use 8 psk demodulation. It should be appreciated that the two demodulation paths are provided in a receiver. This will be discussed in more detail hereinafter.

The GMSK demodulation path 54 has a GMSK demodulator 58. The GMSK demodulator 58 demodulates the received data as if it were modulated in accordance with the GMSK demodulation method.

The demodulated signal is output to a channel estimator 60. The channel estimator 60 calculates the channel impulse response for the channel. 8 taps are provided. The least square estimation method is used but in alternative embodiments of the present invention, different methods may be used. The channel estimator effectively uses the received training symbols and the known training symbols stored in the receiver in memory 62. By making a comparison or correlation between the known and the received training symbols, an estimate of the channel impulse response can be made. The output or taps are the channel impulse responses.

In the next block 64, the maximum energy and time of arrival correction is formed. The 8 channel taps obtained by the channel estimator are sent to a calculator where energy associated with 3 consecutive taps are calculated for various lag variables {index=0, 1, 2, . . 5}. This can be seen in FIG. 7, which shows a typical pattern of the energy of the eight taps. The three consecutive taps which together provide the highest energy, tap 4, 5 and 6 in the example shown in FIG. 7, are selected. The energy is calculated having the following equation:

i=2

Σh(i+j)*h(i+j)

i=0

where j=0, . . . . 5)

In preferred embodiments of the invention, five different energies are calculated. For example the first energy is calculated from the first, second and third taps, the second energy is calculated from the second, third and fourth taps and so on.

In preferred embodiments of the present invention, three out of the eight taps are selected. However, it should be appreciated that in alternative embodiments of the present invention n taps may be selected where n is less the number of taps provided by the channel estimator 60. The channel estimator can of course provide more or less than eight taps. In preferred embodiments of the present invention, the taps succeeding the maximum energy tap are preferably selected, rather than the taps on either side. This is because the maximum tap will usually, but not always, correspond to the shortest path. Accordingly, this means that the taps prior to the tap having the greatest energy are less likely to be related to the signal of interest. However, this will depend on the environment and different selection criteria can be used in different radio propagation environments. The three selected taps are output to the next block 66.

In this approach, the following equation is generally used:

$${σ}^{{2}^{-}} = \frac{1}{N - l + 1} {\sum }_{i = 0}^{i = N - l + 1} {e}_{i} {e}_{i}^{*}$$

where eᵢ represents the error signal and N denotes the number of symbols used for the estimation. The error signal eᵢ is obtained from the received training symbols rᵢ and the reference symbols refᵢ. The received training symbols have, of course, first are demodulated by the GMSK demodulator. rdᵢ is the demodulated received signals and are represented by the following equation:

rdᵢ=rᵢ₊ₗ₋₁₊₆₁e^{-jφ(i+l-1+61)}{i=0,1,2, . . . ,N−l+1

where the index 61 points to first received training position of TDMA signal (i.e the first training symbol in the burst), φ represents the rotation angle. In the case of GMSK, the rotation angle is pi/2. In the case of 8 psk, the rotation angle is 3 pi/8.

The error signal eᵢ is as follows:

eᵢ=rdᵢ−refᵢ₊ₗ₋₁{i=0,1,2, . . . ,N−l+1

refᵢ is computed from the estimated channel impulse response hₖ and the transmitted training symbols xᵢ.

$${ref}_{i} = {\sum }_{k = 0}^{k = l - 1} {x}_{i - k} {h}_{k} \{ i = 0 , 1 , … , N - 1$$

I represents the number of channel impulse responses. The error signal is formed by removing the first I−1 symbols from rᵢ and refᵢ to avoid possible ISI due to the convolution operation. Before starting the convolution the previous symbols are usually assumed to be zero. This assumption causes discontinuity and provides inaccurate output. To avoid this situation the output of the convolution made from these zeros are ignored.

In embodiments of the present invention, the variance is calculated using the following equation:

$${σ}^{2} = \frac{1}{N - l + 1} {\sum }_{i = 0}^{i = N - l + 1} ( {e}_{i} - \overline{e} ) {( {e}_{i} - \overline{e} )}^{*}$$

where \overline{e} represents the mean of eᵢ.

$$\overline{e} = \frac{1}{N - l + 1} {\sum }_{i = 0}^{i = N - l + 1} {e}_{i}$$

In the previously proposed system, the mean error signal eᵢ is assumed to have a zero mean. In contrast, in embodiments of the present invention, the mean value is estimated. The variance is calculated based on the three selected taps.

Reference is made to FIG. 6, which illustrates graphically how the variance is calculated. r represents the input signal, which is demodulated by the demodulator 58 to provide the demodulated output rd. This is in accordance with Equation 2. x represents the known training sequence from which is derived the reference signal ref. This is done by block 68, which uses Equation 4. Block 64 effectively allows the number of taps I to be selected and this is output to block 68. In this embodiment, the number of taps selected is three. Block 66 of FIG. 5 comprises a part 70, which calculates from rd and ref the error signal e. This uses Equation 3. \overline{e} is used by block 72, which computes the variance using Equation 5 and block 74, which computes the mean e using Equation 6. The computed mean \overline{e} is used by block 72, which computes the variance.

Referring back to FIG. 5, 8 psk demodulator path 66 is the same as the GMSK demodulation path, apart from the fact that 8psk demodulator 84 is used instead of the GMSK demodulator 58.

The output of the two blocks 66, which provide the variance, are input to a comparator 86. The path providing the smallest variance provides an indication as to which form of modulation was applied to the received signal. The signal can then be processed once the modulation applied to the received signal has been established.

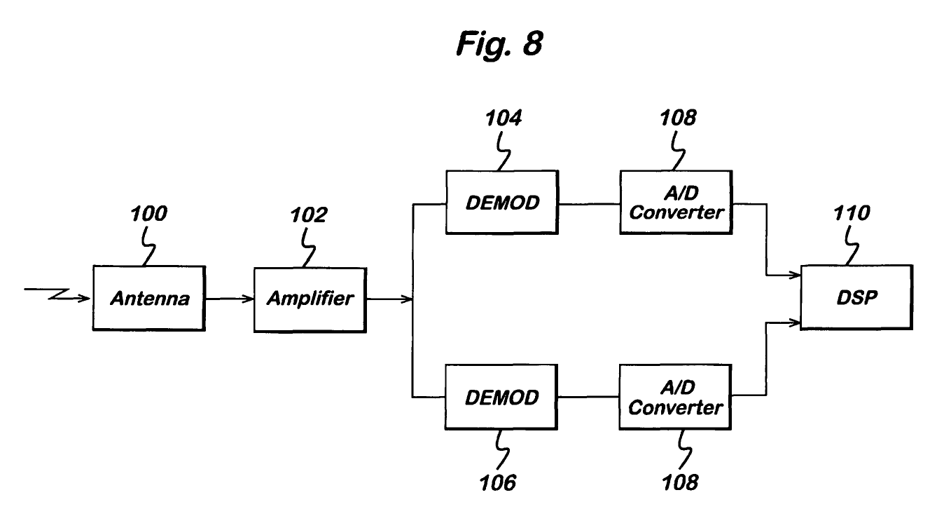

Reference is now made to FIG. 8, which shows schematically a receiver in which embodiments of the present invention can be used. The signal is received by a antenna 100. The received signal 100 is output by the antenna 2 and amplifier 102, which amplifies the signal. The amplified signal is passed to a first demodulator 104 and to a second demodulator 106. One of these demodulators will be the GMSK demodulator, whilst the other will be the 8 psk demodulator. These demodulators 104 and 106, amongst other functions, reduce the received signal to the base band frequency. The output of the demodulators 104 and 106 are output to respective analogue to digital converters 108. These converters convert the received signal to the digital domain. The digital signals are output by the converters to a digital signal processor 110 which processes the received signal. It should be appreciated that the demodulators 58 and 84 are provided by the demodulators 104 and 106. The remainder of the demodulation paths illustrated in FIG. 5 are provided in the digital signal processor. It should be appreciated that whilst the representation of the embodiment of the invention shown in FIG. 5 shows separate blocks for providing separate functions, in practice, these blocks may be notional blocks rather than actual physical blocks.

Embodiments of the present invention can be used with standards other than GSM and with modulation methods other than 8 psk and GMSK. Embodiments of the invention can be used where there are more than two possible modulation methods.

1. A method for determining a modulation method applied to a received signal, said method comprising:
demodulating said received signal using at least two different modulation methods;
determining for each demodulated signal an estimate of said channel, said estimate of said channel comprising m taps;
selecting n of said taps for each channel estimate, n being less than m;
estimating a variance for each demodulated signal based on said n taps; and
comparing the estimated variances and based on said comparison making a determination as to the modulation method applied to the received signal.

2. A method as claimed in claim 1, wherein in the step of estimating the variance, a mean of an error of at least a portion of said signal is used.

3. A method as claimed in claim 2, wherein said mean is calculated in accordance with the following equation:
$$\overline{e} = \frac{1}{N - l + 1} {\sum }_{i = 0}^{i = N - l + 1} {e}_{i}$$

4. A method as claimed in claim 2 or 3, wherein said portion comprises a known portion of said signal.

5. A method as claimed in claim 2, 3 or 4, wherein the following equation is used to calculate the variance:
$${σ}^{2} = \frac{1}{N - l + 1} {\sum }_{i = 0}^{i = N - l + 1} ( {e}_{i} - \overline{e} ) {( {e}_{i} - \overline{e} )}^{*}$$

6. A method as claimed in any preceding claim, wherein in said selection step, the taps are selected in dependence on the energy of said taps.

7. A method as claimed in claim 6, wherein the tap having the highest energy is determined and selected as one of said taps along with the n-1 successive taps.

8. A method as claimed in any preceding claim, wherein said received signal includes a known portion.

9. A method as claimed in claim 8, wherein channel is estimated by comparing the received version of the known portion with what said known portion should be.

10. A method as claimed in any preceding claim, wherein said received signal is in accordance with the GSM standard.

11. A method as claimed in 4 or 8, wherein said known portion comprises a training sequence.

12 A method as claimed in any preceding claim, wherein at least one of said modulation methods comprises at least one of the following modulation methods: GMSK and 8 -psk.

13. A method as claimed in any preceding claim, wherein m is 8.

14. A method as claimed in any preceding claim, wherein n is 3.

15. A method as claimed in any preceding claim, wherein said channel impulse response is determined in said determining step.

16. A method as claimed in claim, wherein said channel impulse response is estimated using the least square method.

17. A method for determining a modulation method applied to a received signal, said method comprising:
demodulating said received signal using at least two different modulation methods;
determining for each demodulated signal an estimate of said channel,;
estimating a variance for each demodulated signal based on said channel estimates, said variance taking into account a mean error for at least a portion of said received signal; and
comparing the estimated variances and based on said comparison making a determination as to the modulation method applied to the received signal.

18. A receiver for determining a modulation method applied to a received signal, said receiver comprising:
means for demodulating said received signal using at least two different modulation methods;
means for determining for each demodulated signal an estimate of said channel, said estimate of said channel comprising m taps;
means for selecting n of said taps for each channel estimate, n being less than m; means for estimating a variance for each demodulated signal based on said n taps; and
means for comparing the estimated variances and based on said comparison making a determination as to the modulation method applied to the received signal.

19. A receiver for determining a modulation method applied to a received signal, said receiver comprising:
means for demodulating said received signal using at least two different modulation methods;
means for determining for each demodulated signal an estimate of said channel,;
means for estimating a variance for each demodulated signal based on said channel estimates, said variance taking into account a mean error for at least a portion of said received signal; and
means for comparing the estimated variances and based on said comparison making a determination as to the modulation method applied to the received signal.
